(19) United States
(12) Patent Application Publication
(10) Pub. No.: US 2012/0000513 A1
(43) Pub. Date: Jan. 5, 2012

(54) ANTI-THEFT APPARATUS FOR SOLAR PANELS

(75) Inventors: Ahiezer BEN IZHAK, Kfar Menachem (IL); Daniel FEINMAN, Arugot (IL)

(73) Assignee: SOLARIS ENERGY SYSTEMS LTD., Kfar Shemaryahu (IL)

(21) Appl. No.: 13/174,016

(22) Filed: Jun. 30, 2011

Related U.S. Application Data
(60) Provisional application No. 61/360,613, filed on Jul. 1, 2010.
(60) Provisional application No. 61/423,755, filed on Dec. 16, 2010.

(30) Foreign Application Priority Data
Mar. 27, 2011 (IL) PCT/IL2011/000278

(51) Int. Cl. H01L 31/048; E05B 73/00

(52) U.S. Cl. 136/251; 70/58

(57) ABSTRACT

Anti-theft apparatus for protecting solar electricity generating panels from theft including at least a first lockable element configured for engagement with a first solar electricity generating panel, at least a second lockable element configured for engagement with a second solar electricity generating panel, at least one locking element for securing the at least first and the at least second lockable elements together in a locking arrangement whereby the first and second solar electricity generating panels are at least locked together, and a top securing element arranged for non-removable engagement with the locking element, the top securing element being operative to resist disengagement of the first and the second solar electricity generating panels from the locking element.

### REFERENCE TO RELATED APPLICATIONS

Reference is hereby made to U.S. Provisional Patent Application Ser. No. 61/360,613, filed Jul. 1, 2010 and entitled “SECURITY SYSTEM FOR SOLAR PANELS”, and to U.S. Provisional Patent Application Ser. No. 61/423,755, filed Dec. 16, 2010 and entitled “ANTI-THEFT SYSTEM FOR SOLAR PANELS”, the disclosures of which are hereby incorporated by reference and priority of which are hereby claimed pursuant to 37 CFR 1.78(a)(4) and (5)(i).

Reference is also made to PCT Patent Application PCT/IL2011/000278, filed Mar. 27, 2011 and entitled “ANTI-THEFT APPARATUS FOR SOLAR PANELS”, the disclosure of which is hereby incorporated by reference and priority of which is hereby claimed pursuant to 37 CFR 1.78(a)(1) and (2)(i).

### FIELD OF THE INVENTION

The present invention relates generally to anti-theft apparatus for use with photovoltaic panels.

### BACKGROUND OF THE INVENTION

The following patent publications are believed to represent the current state of the art:

U.S. Published Patent Applications 2010/0206018 and 2010/0141424.

### SUMMARY OF THE INVENTION

The present invention seeks to provide improved anti-theft apparatus for use with photovoltaic panels.

There is thus provided in accordance with a preferred embodiment of the present invention anti-theft apparatus for protecting solar electricity generating panels from theft including at least a first lockable element configured for engagement with a first solar electricity generating panel, at least a second lockable element configured for engagement with a second solar electricity generating panel, at least one locking element for securing the at least first and the at least second lockable elements together in a locking arrangement whereby the first and second solar electricity generating panels are at least locked together, and a top securing element arranged for non-removable engagement with the locking element, the top securing element being operative to resist disengagement of the first and the second solar electricity generating panels from the locking element.

In accordance with a preferred embodiment of the present invention, the apparatus is also configured to be securable to a support upon which the first and the second solar electricity generating panels are mounted. Preferably, each of the at least first and the at least second lockable elements are configured for engagement with a protective cable.

There is also provided in accordance with another preferred embodiment of the present invention a theft-protected array of solar electricity generating panels, the theft-protected array including a multiplicity of solar electricity generating panels mounted on a support structure, and a locking assembly for locking adjacent ones of the multiplicity of solar electricity generating panels to each other, but not locking each of the multiplicity of solar electricity generating panels to all of the panels adjacent thereto in the array, the locking assembly being configured to be securable to the support structure and being operative to prevent lateral movement of the multiplicity of solar electricity generating panels relative to the support structure.

Preferably, the locking assembly includes at least a first lockable element configured for engagement with a first solar electricity generating panel of the multiplicity of solar electricity generating panels, at least a second lockable element configured for engagement with a second solar electricity generating panel of the multiplicity of solar electricity generating panels, and at least one locking element for securing the at least first and the at least second lockable elements together in a locking arrangement whereby the first and second solar electricity generating panels are at least locked together.

Preferably, the theft-protected array of solar electricity generating panels also includes a tamper responsive protective cable extending through the locking assembly, whereby tampering with the locking assembly provides an alarm indication.

There is further provided in accordance with yet another preferred embodiment of the present invention a theft-protected array of solar electricity generating panels, the theft-protected array including a multiplicity of solar electricity generating panels mounted on a support structure, a locking assembly for locking adjacent ones of the multiplicity of solar electricity generating panels to each other, the locking assembly being configured to be securable to the support structure and also being operative to prevent lateral movement of the multiplicity of solar electricity generating panels respective the support structure, and a tamper responsive protective cable extending through the locking assembly, whereby tampering with the locking assembly provides an alarm indication.

Preferably, the locking assembly includes at least a first lockable element configured for engagement with a first solar electricity generating panel of the multiplicity of solar electricity generating panels, at least a second lockable element configured for engagement with a second solar electricity generating panel of the multiplicity of solar electricity generating panels, and at least one locking element for securing the at least first and the at least second lockable elements together in a locking arrangement whereby the first and second solar electricity generating panels are at least locked together.

There is yet further provided in accordance with still another preferred embodiment of the present invention anti-theft apparatus for protecting solar electricity generating panels from theft including a first lockable element configured for engagement with a first solar electricity generating panel a second lockable element configured for engagement with a second solar electricity generating panel a spacer element, and a top securing element arranged for non-removable engagement with the spacer element, the top securing element being operative to resist disengagement of the first and the second solar electricity generating panels from the spacer element, the first and second lockable elements and the spacer element being lockable together in a locking arrangement whereby the first and second solar electricity generating panels are prevented by the spacer element from being brought closer together to each other.

Preferably, the apparatus is also configured to be securable to a support upon which the first and the second solar electricity generating panels are mounted. Preferably, the apparatus is configured for engagement with a protective cable.

There is also provided in accordance with another preferred embodiment of the present invention a theft-protected array of solar electricity generating panels, the theft-protected array including a multiplicity of solar electricity generating panels mounted in a mutually spaced arrangement in a plane on a support structure, and a locking assembly for locking adjacent ones of the multiplicity of solar electricity generating panels to each other, the locking assembly being configured to be securable to the support structure, the locking assembly including a spacer element operative to prevent the first and second solar electricity generating panels from being brought closer together to each other than in the mutually spaced arrangement in the plane, and engagement elements operative to prevent lateral movement of the first and second solar electricity generating panels relative to the support structure.

Preferably, the theft-protected array of solar electricity generating panels also includes a tamper responsive protective cable extending through the locking assembly, whereby tampering with the locking assembly provides an alarm indication.

### BRIEF DESCRIPTION OF THE DRAWINGS

The present invention will be understood and appreciated more fully from the following detailed description, taken in conjunction with the drawings in which:

FIGS. 1A and 1B are simplified respective exploded view and assembled view illustrations of anti-theft apparatus constructed and operative in accordance with a preferred embodiment of the present invention;

FIGS. 2A, 2B, 2C, 2D and 2E are simplified illustrations of a first element employed in the apparatus of FIGS. 1A & 1B, FIG. 2B being taken along lines IIB-IIB in FIG. 2A, FIG. 2D being taken along lines IID-IID in FIG. 2C and FIG. 2E being taken along lines IIE-IIE in FIG. 2C;

FIGS. 3A, 3B and 3C are simplified illustrations of a second element employed in the apparatus of FIGS. 1A & 1B;

FIGS. 4A, 4B and 4C are simplified illustrations of a third element employed in the apparatus of FIGS. 1A & 1B;

FIGS. 5A and 5B are simplified pictorial illustration of a fourth element employed in the apparatus of FIGS. 1A & 1B;

FIGS. 6A, 6B, 6C, 6D and 6E are simplified illustrations of various stages in the use of the apparatus of FIGS. 1A & 1B in preventing theft of an array of solar electricity generating panels.

### DETAILED DESCRIPTION OF PREFERRED EMBODIMENTS

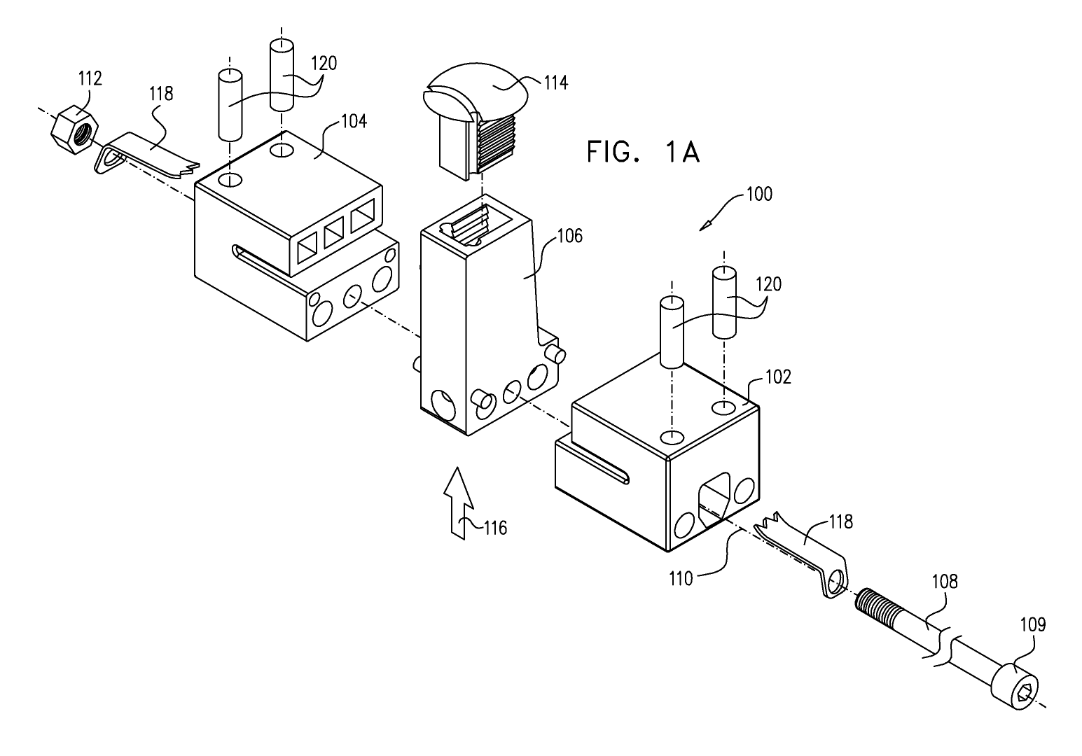

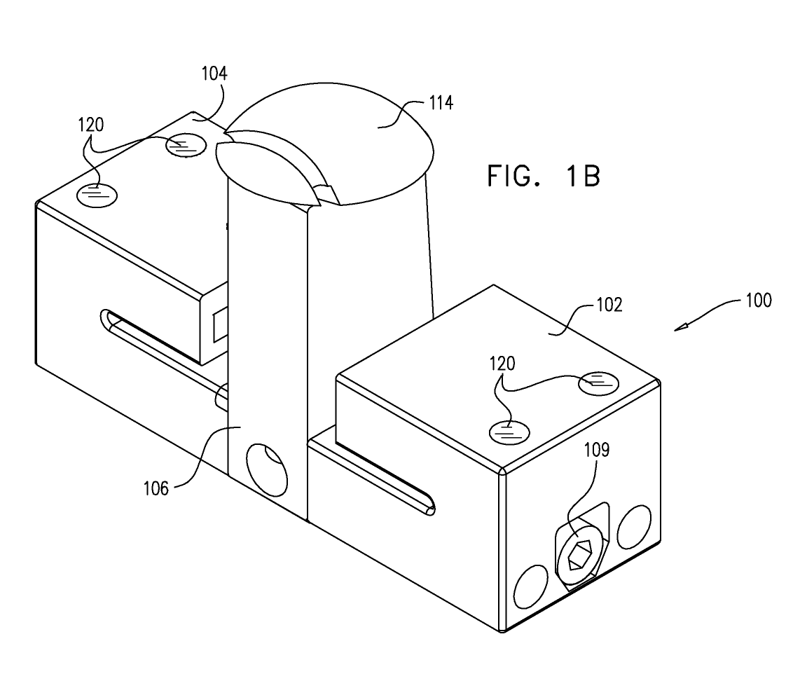

Reference is now made to FIGS. 1A and 1B, which are simplified respective exploded view and assembled view illustrations of anti-theft apparatus 100 constructed and operative in accordance with a preferred embodiment of the present invention.

As seen in FIGS. 1A & 1B, the anti-theft apparatus 100 preferably includes a first lockable element 102 configured for engagement with a first solar electricity generating panel (not shown), a second lockable element 104, preferably generally identical to first locking element 102, configured for engagement with a second solar electricity generating panel (not shown) and an intermediate lockable element 106 configured for engagement with first and second lockable elements 102 and 104 and with first and second solar electricity generating panels. At least one locking element, such as a threaded rod 108 having a screw head 109, preferably extends through elements 102, 104 and 106 along an axis 110 and is engaged by a nut 112, for securing the first and second lockable elements 102 and 104 together in a locking arrangement whereby the first and second solar electricity generating panels are at least locked together.

In accordance with a preferred embodiment of the present invention, a top securing element 114 is arranged for non-removable engagement with intermediate lockable element 106, thereby to resist disengagement of the first and second solar electricity generating panels from the intermediate lockable element 106 by lifting them in a direction 116, perpendicular to axis 110.

Additionally in accordance with a preferred embodiment of the present invention first and second engagement elements 118 are provided for tight engagement with the first and second solar electricity generating panels when threaded rod 108, on which they are mounted is tightly engaged by nut 112.

A pair of hardened pins 120 are preferably provided for inserting into each of first lockable element 102 and second lockable element 104.

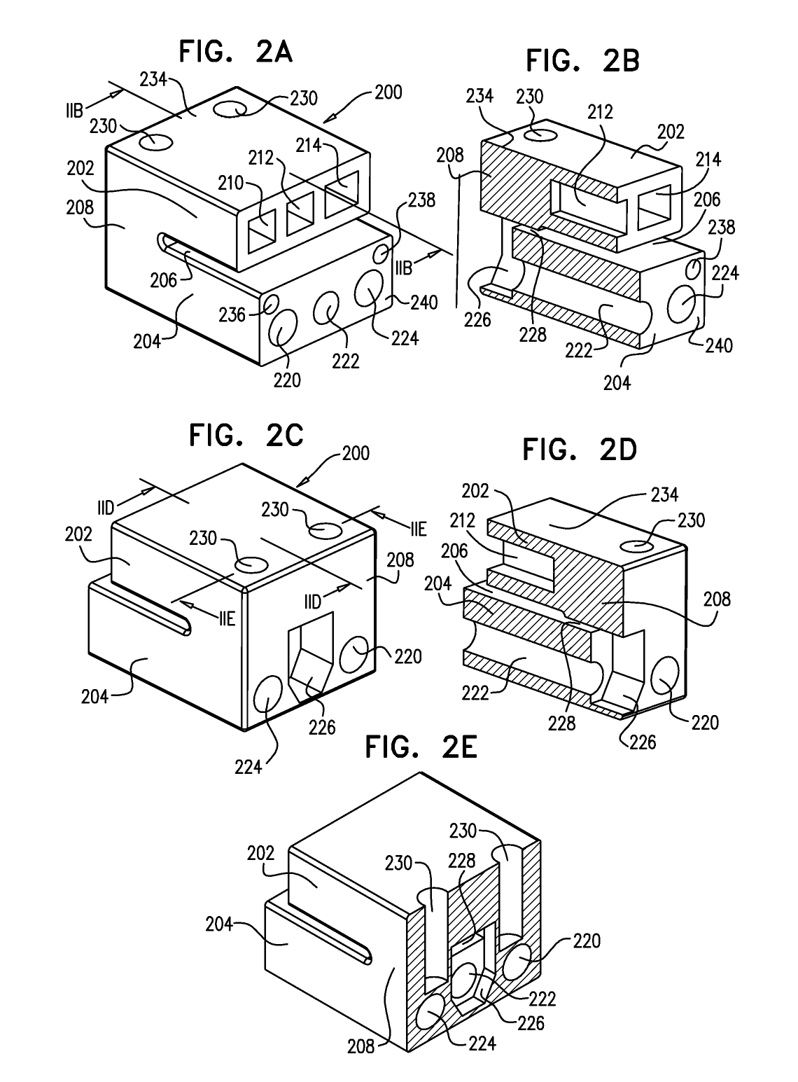

Reference is now made to FIGS. 2A, 2B, 2C, 2D and 2E, which are simplified illustrations of a lockable element 200 preferably employed in the apparatus of FIGS. 1A & 1B as lockable elements 102 and 104.

As seen in FIGS. 2A-2E, lockable element 200 preferably is integrally formed in an asymmetrical U-shape, from a suitable material, typically a plastic such as Nylon 66. In the sense shown in FIGS. 2A-2E, lockable element 200 includes an upper, shorter leg 202, a lower, longer leg 204, spaced from upper, shorter leg 202 by a slot 206, and a joining portion 208, integrally joining legs 202 and 204.

Upper, shorter leg 202 preferably is formed with three side-by-side recesses 210, 212 and 214, preferably having generally square cross-sections. Lower, longer leg 204 preferably is formed with three side-by-side throughgoing bores 220, 222 and 224, preferably having generally round cross-sections. Bore 222 is preferably formed with a broadened recess 226, at one end thereof. Recess 226 communicates with slot 206 preferably by means of an intermediate slit 228.

A pair of recesses 230 extend partially through joining portion 208 from a top surface 234 thereof. Hardened pins 120 (FIG. 1A), preferably formed of hardened metal, are preferably inserted in recesses 230 in elements 200 for resisting attempts to drill or cut therethrough. Alternatively, lockable element 200 may be formed with one or more hardened portions and recesses 230 and pins 120 may be obviated.

Shallow pin sockets 236 and 238 extend through lower, longer leg 204 from an end surface 240 thereof.

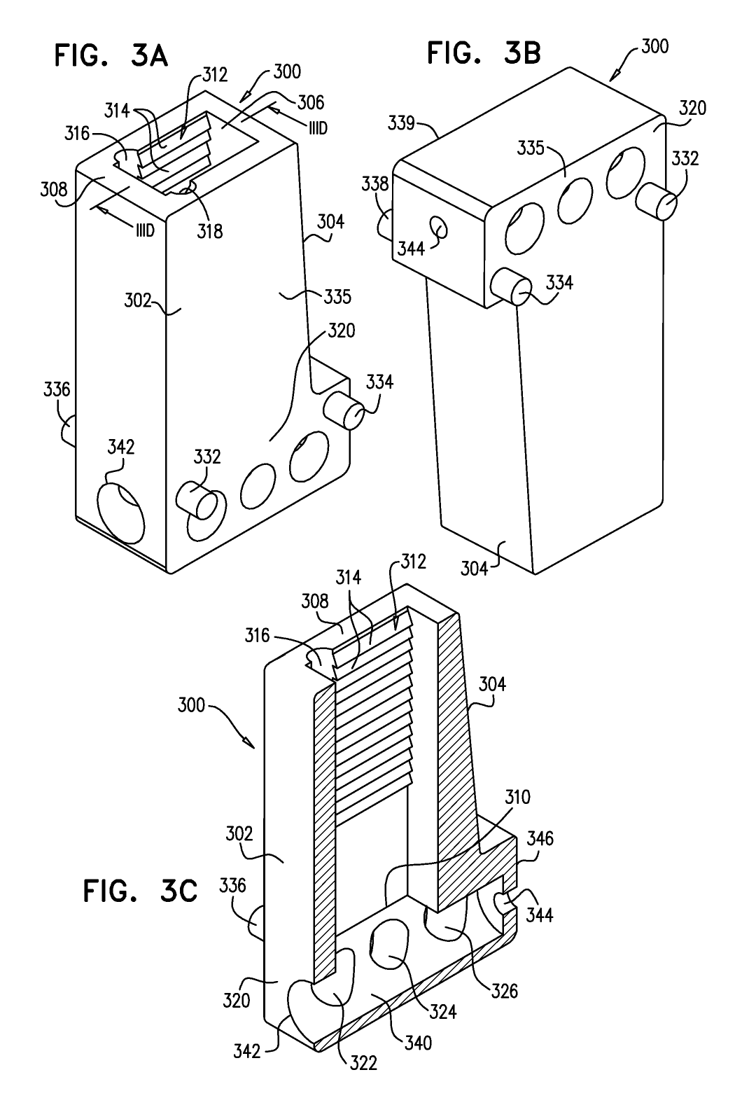

Reference is now made to FIGS. 3A, 3B and 3C, which are simplified illustrations of an element 300, preferably employed in the apparatus of FIGS. 1A & 1B as intermediate lockable element 106.

Preferably, element 300 is integrally formed from a suitable material, typically a plastic such as Nylon 66. In the sense shown in FIGS. 3A-3C, element 300 includes an upper portion 302 having an inclined edge surface 304. Upper portion also includes a generally rectangular bore 306 extending downwardly from an upper face 308 of upper portion 302 to a lower end 310 of upper portion 302.

Rectangular bore 306 preferably includes two gear racks 312 integrally formed on opposite walls of bore 306, each of gear racks 312 comprising an array of saw tooth-like elements 314, and is arranged for receiving top securing element 114 (FIGS. 1A & 1B) in tight non-removable engagement with gear racks 312. Recesses 316 and 318 are preferably formed on opposite sides of bore 306 and extend alongside gear racks 312 from upper face 308 to lower end 310.

Element 300 also includes a lower portion 320, formed with three side-by-side throughgoing bores 322, 324 and 326, preferably having generally round cross-sections. Alignment pins 332 and 334 extend outwardly from lower portion 320 at side 335 of element 300 and alignment pins 336 and 338 extend outwardly from lower portion 320 at side 339 of element 300.

A bore 340 extends through most of lower portion 320, generally perpendicularly to and intersecting bores 322, 324 and 326 from a edge 342 of element 300 and terminates in a reduced size aperture 344 at an opposite facing edge 346 of element 300. Bore 340 also perpendicularly intersects bore 306.

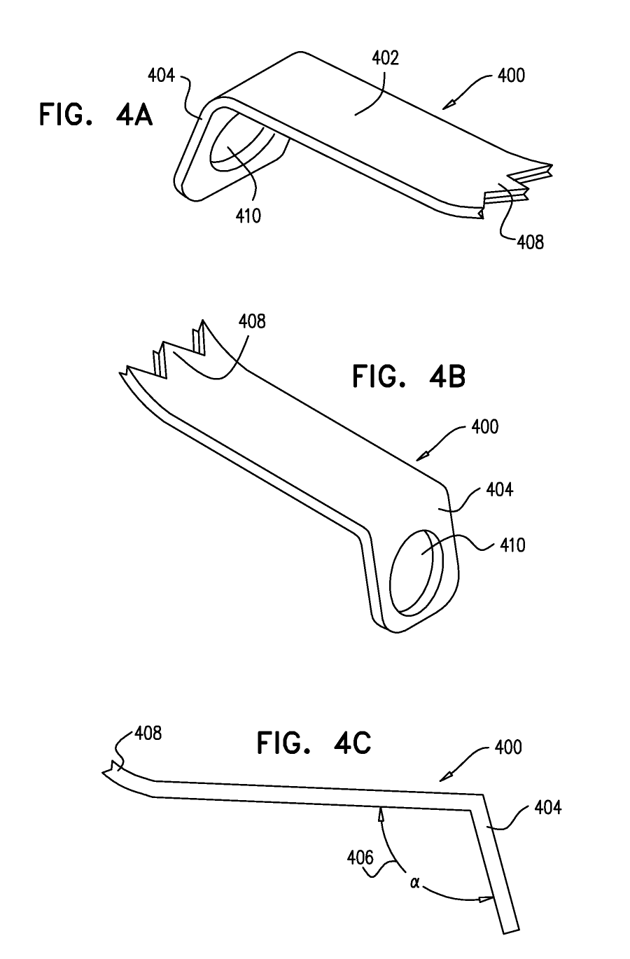

Reference is now made to FIGS. 4A, 4B and 4C, which are simplified illustrations of an element 400, preferably employed in the apparatus of FIGS. 1A & 1B as first and second engagement elements 118. Element 400 is preferably integrally formed of hardened metal.

As seen in FIGS. 4A-4C, element 400 includes a generally planar upper portion 402 and an inclined side portion 404. Preferably, portions 402 and 404 define an obtuse angle 406 therebetween. Upper portion 402 includes a serrated edge 408 which curves slightly upwards of the plane of portion 402 in the sense shown in FIGS. 4A-4C. Side portion 404 includes a circular bore 410 for accommodating rod 108 (FIGS. 1A & 1B).

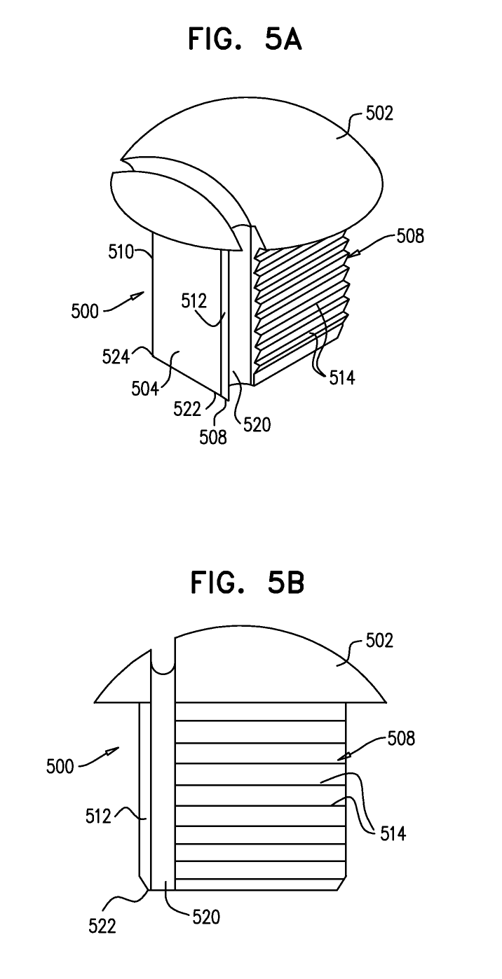

Reference is now made to FIGS. 5A and 5B, which are simplified pictorial illustration of an element 500, preferably employed in the apparatus of FIGS. 1A & 1B as top securing element 114. Preferably, element 500 is integrally formed from a suitable material, typically a plastic such as Nylon 66. In the sense shown in FIGS. 5A & 5B, element 500 includes an upper generally dome-like portion 502 and a lower portion 504. Lower portion 504 includes two gear racks 506 and 508 integrally formed on respective opposite sides 510 and 512 thereof, each of which gear racks 506 and 508 comprising an array of saw tooth-like elements 514 arranged for tight non-removable engagement with tooth-like elements 314 of gear racks 312 of rectangular bore 306 (FIG. 3) upon insertion therein.

A recess 520 integrally formed in element 500 preferably extends from a bottom end 522 of side 512 upwards alongside gear rack 508, along a generally chord-like path over an upper surface of dome-like portion 502 and downwards to a bottom end 524 of side 510 alongside gear rack 506 (not shown).

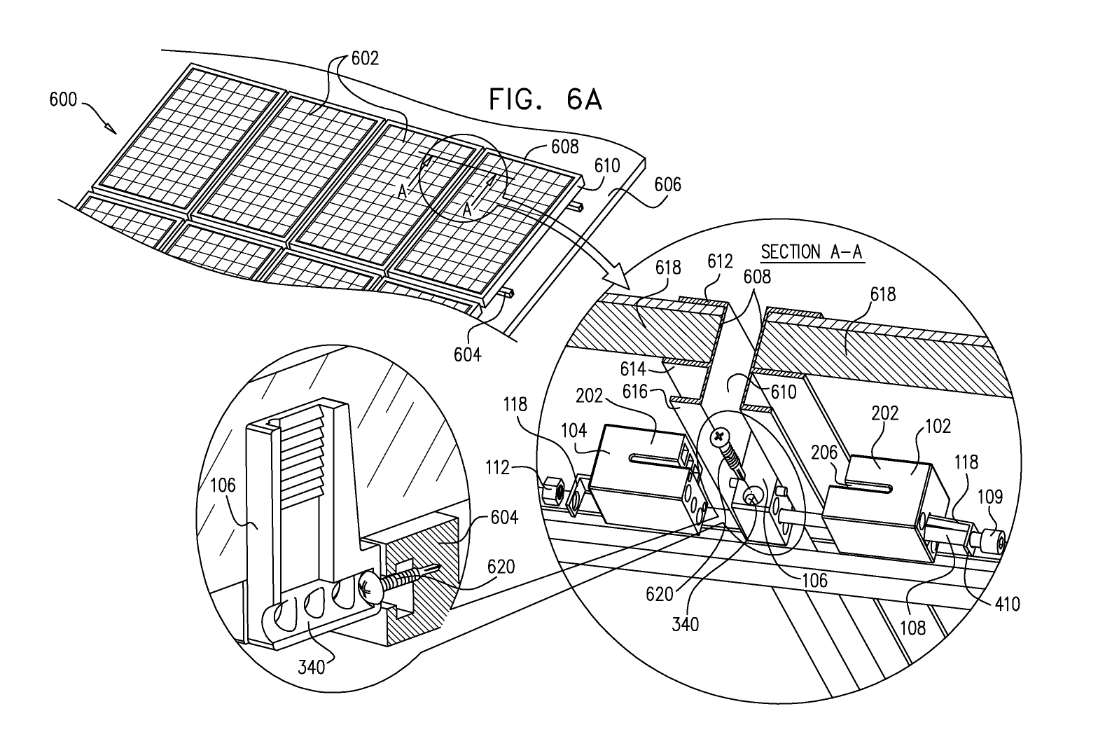

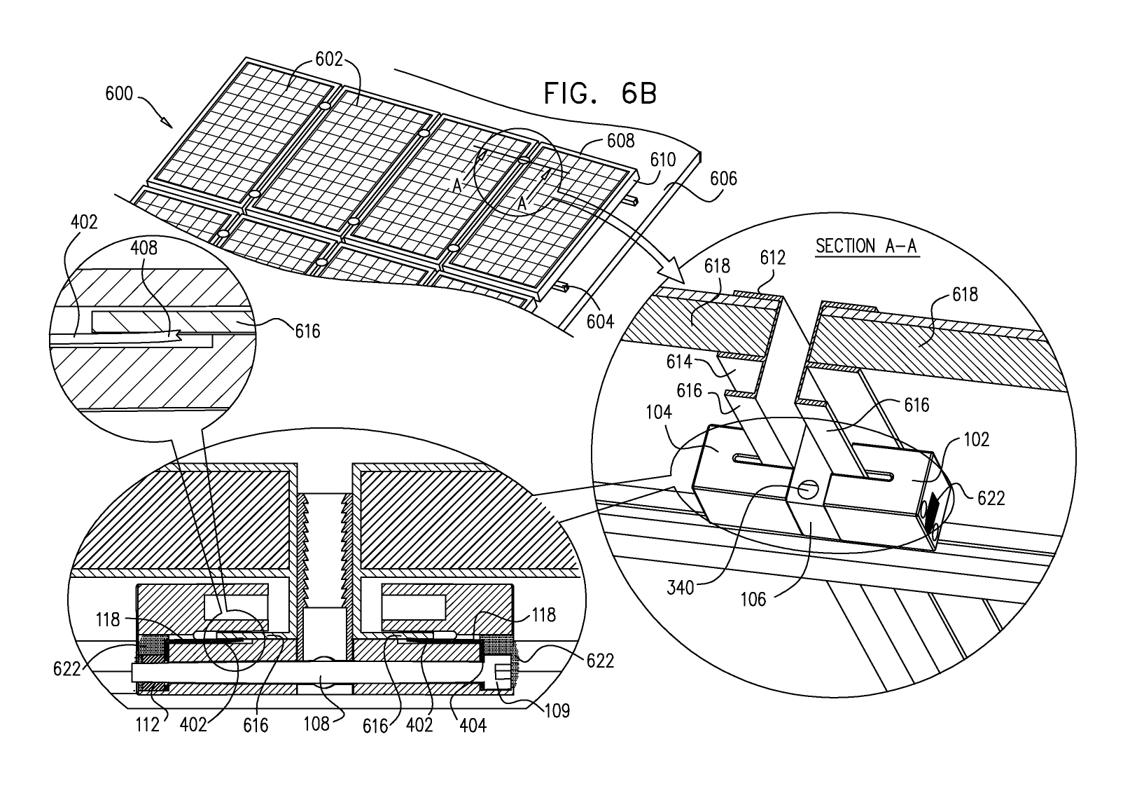

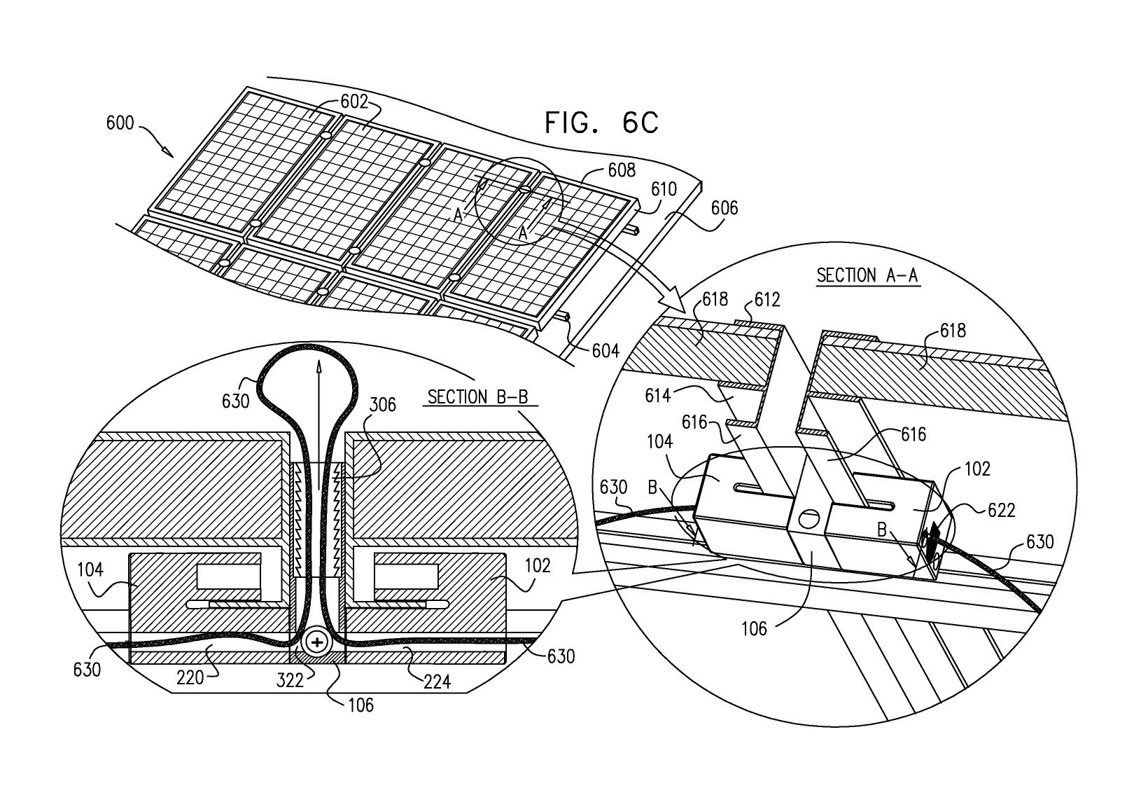

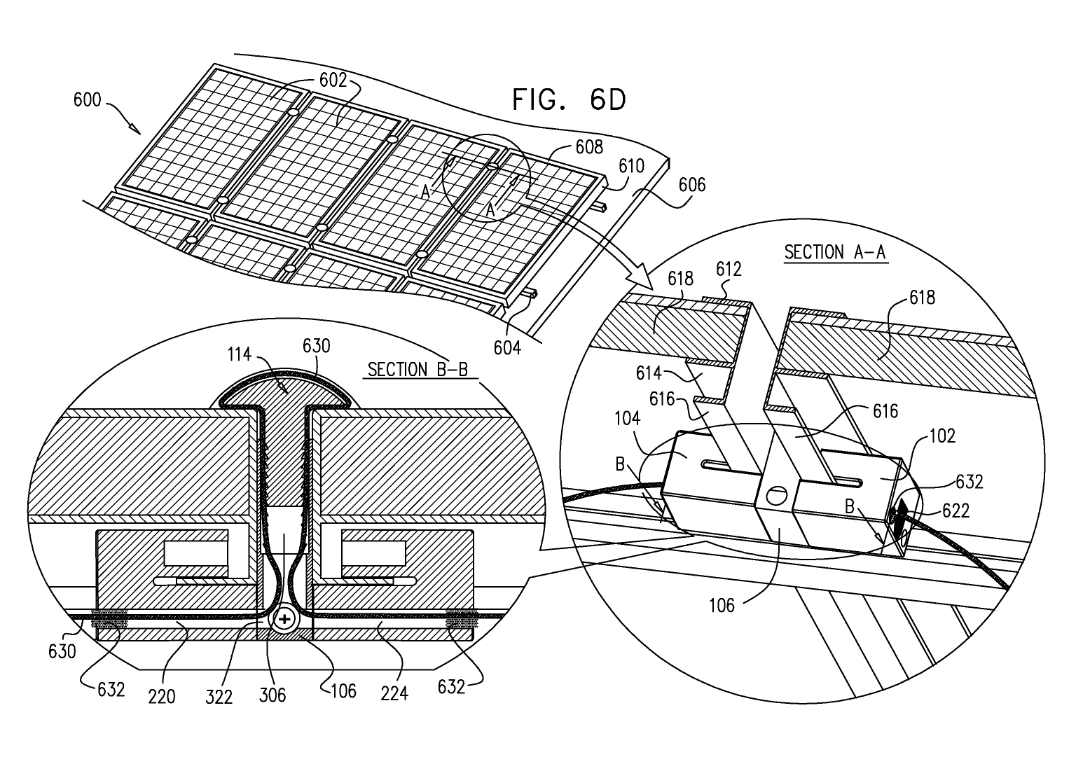

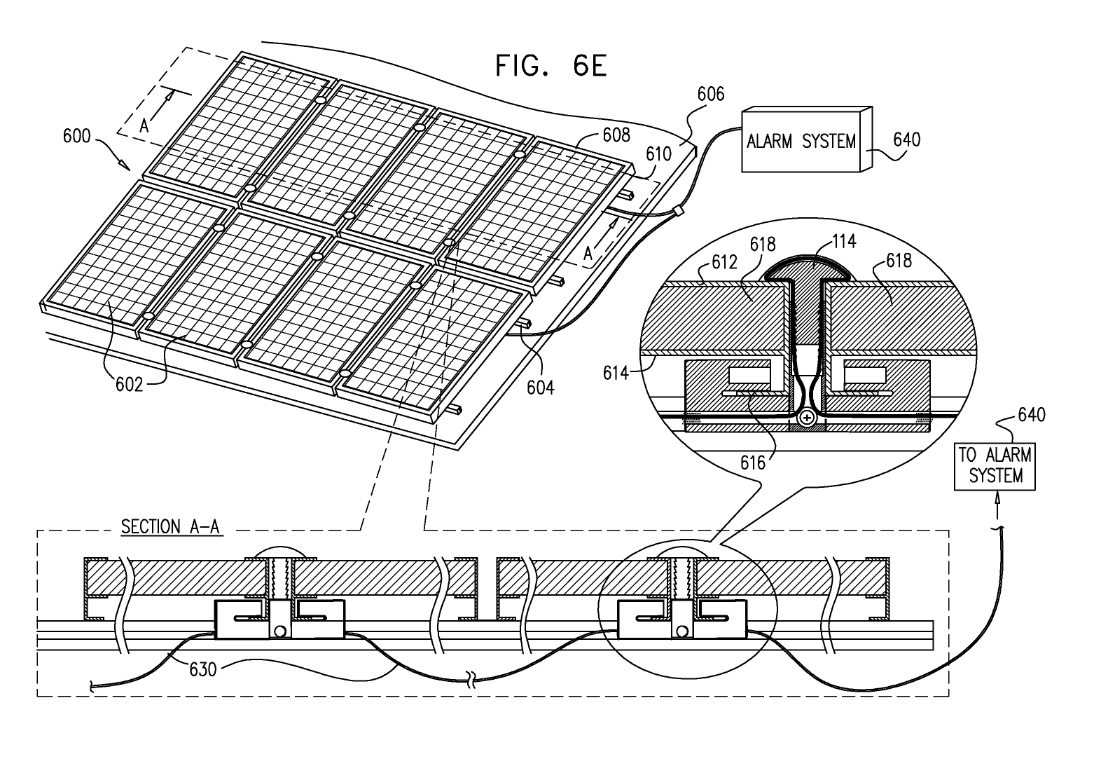

Reference is now made to FIGS. 6A, 6B, 6C, 6D and 6E, which are simplified illustrations of various stages in the installation of the apparatus of FIGS. 1A & 1B in preventing theft of an array of solar electricity generating panels.

Turning to FIG. 6A, it is seen that an array 600 of solar electricity generating panels 602 is mounted via elongate mounting supports 604 on a support surface 606, such as a roof. Each of solar electricity generating panels 602 is typically provided with an extruded peripheral aluminum rim 608 which includes an integrally formed planar back strip portion 610 from which extend, generally perpendicularly, three mutually spaced strips, here designated by reference numerals 612, 614 and 616. A planar electricity generating panel portion 618 is retained between respective strips 612 and 614, extending peripherally and circumferentially with respect thereto.

FIG. 6A illustrates an initial stage in mounting the apparatus of FIGS. 1A & 1B for preventing theft of panels 602. Intermediate lockable element 106 is secured onto elongate mounting support 604, preferably by a self-boring screw 620, which is inserted via bore 340 and is seated against reduced size aperture 344 at an opposite facing edge 346 (FIGS. 3A-3C).

Elements 102 and 104 are aligned in mutually facing, spaced arrangement such that their upper, shorter legs 202 are arranged to be partially inserted between strips 614 and 616 of respective rims 608 of adjacent solar electricity generating panels 602. Slots 206 of respective elements 102 and 104 are arranged to receive respective strips 616 of adjacent solar electricity generating panels 602. Threaded rod 108 is shown extended through bore 410 of engagement element 118 and through bore 222 of element 102.

It is appreciated that hardened pins 120 (FIG. 1A) are preferably inserted in recesses 230 in elements 102 and 104 prior to mounting of elements 102 and 104 to panels 602.

Turning now to FIG. 6B, it is seen that elements 102 and 104 are locked together with intermediate element 106 by rod 108, which extends through bores 222 of elements 102 and 104, bores 410 of first and second engagement elements 118 and bore 324 in element 106, in threaded engagement with nut 112. Upper portions 402 of first and second engagement elements 118 are disposed within intermediate slits 228 of elements 102 and 104. Side portions 404 of first and second engagement elements 118 are tightly retained within broadened recesses 226 of elements 102 and 104 by screw end 109 and nut 112 respectively. Strips 616 are seated in slots 206 of respective elements 102 and 104 in engagement with upper portions 402 of first and second engagement elements 118.

It is a particular feature of the present invention that pressure applied to side portions 404 by screw end 109 and nut 122 is transferred to upwardly curving serrated edges 408 of upper portions 402 thereby causing serrated edges 408 to bite into strips 616 and retain them, and thereby preventing lateral movement of elements 102 and 104 relative to strips 616.

Access to nut 112 and to screw end 109 is preferably blocked by plugs of epoxy, indicated by reference numeral 622. Rod 108 blocks access to screw 620 in bore 340.

FIG. 6C additionally shows a tamper responsive protective cable 630 extending through bore 224 of element 102, bores 322 and 306 of element 106 and bore 220 of element 104.

As further shown in FIG. 6D, top securing element 114 is inserted into bore 306 after the insertion of cable 630, whereby tight non-removable engagement of gear racks 506 and 508 of top securing element 114 with gear racks 312 of bore 306 is operative to prevent removal of element 114 from bore 306, and thereby is also operative to resist disengagement of the first and second solar electricity generating panels from the intermediate lockable element 106 by lifting them in a direction perpendicular to axis 110.

Cable 630 is disposed within recess 520 of element 114 (FIGS. 5A & 5B), whereby sections of cable 430 extending through bore 306 are disposed within a circular bore created by mutual alignment of recess 520 of element 114 with recesses 316 and 318 of bore 306, and is pulled taut through bores 220 and 224. Cable 630 is then preferably sealed to bores 220 and 224 by an adhesive, such as epoxy, as indicated by reference numerals 632. It is appreciated that the tight non-removable engagement of element 114 within bore 306 is also operative to prevent removal of cable 430 from recess 520.

As seen further in FIG. 6E, a plurality of protective cables 630, such as a solid strand size 30 hook-up wire, part number 2030, commercially available from WEICO Wire and Cable, Inc. of Edgewood, N.Y., USA, or an AWG 4×22 HFFR or PVC covered wire, commercially available from Reouel, LTD. of Moshav Yad-Rambam, Israel, each preferably extending through multiple locked assemblies of elements 102, 104 and 106, are preferably coupled to an alarm system 640, such as a PIMA Hunter Pro 33, commercially available from PIMA Electronic Systems, Ltd. of Holon, Israel, which provides an alarm indication of cutting of cables 630.

It will be appreciated by persons skilled in the art that the present invention is not limited by what has been particularly shown and described hereinabove. Rather the scope of the present invention includes both combinations and subcombinations of the various features described hereinabove as well as modifications thereof which would occur to persons skilled in the art upon reading the foregoing description and which are not in the prior art.

1. Anti-theft apparatus for protecting solar electricity generating panels from theft comprising:
at least a first lockable element configured for engagement with a first solar electricity generating panel;
at least a second lockable element configured for engagement with a second solar electricity generating panel;
at least one locking element for securing said at least first and said at least second lockable elements together in a locking arrangement whereby said first and second solar electricity generating panels are at least locked together; and
a top securing element arranged for non-removable engagement with said locking element, said top securing element being operative to resist disengagement of said first and said second solar electricity generating panels from said locking element.

2. Anti-theft apparatus for protecting solar electricity generating panels from theft according to claim 1 and wherein said apparatus is also configured to be securable to a support upon which said first and said second solar electricity generating panels are mounted.

3. Anti-theft apparatus for protecting solar electricity generating panels from theft according to claim 1 and wherein each of said at least first and said at least second lockable elements are configured for engagement with a protective cable.

4. A theft-protected array of solar electricity generating panels, said theft-protected array comprising:
a multiplicity of solar electricity generating panels mounted on a support structure; and
a locking assembly for locking adjacent ones of said multiplicity of solar electricity generating panels to each other, but not locking each of said multiplicity of solar electricity generating panels to all of the panels adjacent thereto in said array, said locking assembly being configured to be securable to said support structure and being operative to prevent lateral movement of said multiplicity of solar electricity generating panels relative to said support structure.

5. A theft-protected array of solar electricity generating panels according to claim 4 and wherein said locking assembly comprises:
at least a first lockable element configured for engagement with a first solar electricity generating panel of said multiplicity of solar electricity generating panels;
at least a second lockable element configured for engagement with a second solar electricity generating panel of said multiplicity of solar electricity generating panels; and
at least one locking element for securing said at least first and said at least second lockable elements together in a locking arrangement whereby said first and second solar electricity generating panels are at least locked together.

6. A theft-protected array of solar electricity generating panels according to claim 4 and also comprising a tamper responsive protective cable extending through said locking assembly, whereby tampering with said locking assembly provides an alarm indication.

7. A theft-protected array of solar electricity generating panels, said theft-protected array comprising:
a multiplicity of solar electricity generating panels mounted on a support structure;
a locking assembly for locking adjacent ones of said multiplicity of solar electricity generating panels to each other, said locking assembly being configured to be securable to said support structure and also being operative to prevent lateral movement of said multiplicity of solar electricity generating panels respective said support structure; and
a tamper responsive protective cable extending through said locking assembly, whereby tampering with said locking assembly provides an alarm indication.

8. A theft-protected array of solar electricity generating panels according to claim 7 and wherein said locking assembly comprises:
at least a first lockable element configured for engagement with a first solar electricity generating panel of said multiplicity of solar electricity generating panels;
at least a second lockable element configured for engagement with a second solar electricity generating panel of said multiplicity of solar electricity generating panels; and
at least one locking element for securing said at least first and said at least second lockable elements together in a locking arrangement whereby said first and second solar electricity generating panels are at least locked together.

9. Anti-theft apparatus for protecting solar electricity generating panels from theft comprising:
a first lockable element configured for engagement with a first solar electricity generating panel;
a second lockable element configured for engagement with a second solar electricity generating panel;
a spacer element; and
a top securing element arranged for non-removable engagement with said spacer element, said top securing element being operative to resist disengagement of said first and said second solar electricity generating panels from said spacer element;
said first and second lockable elements and said spacer element being lockable together in a locking arrangement whereby said first and second solar electricity generating panels are prevented by said spacer element from being brought closer together to each other.

10. Anti-theft apparatus for protecting solar electricity generating panels from theft according to claim 9 and wherein said apparatus is also configured to be securable to a support upon which said first and said second solar electricity generating panels are mounted.

11. Anti-theft apparatus for protecting solar electricity generating panels from theft according to claim 9 and wherein said apparatus is configured for engagement with a protective cable.

12. A theft-protected array of solar electricity generating panels, said theft-protected array comprising:
a multiplicity of solar electricity generating panels mounted in a mutually spaced arrangement in a plane on a support structure; and
a locking assembly for locking adjacent ones of said multiplicity of solar electricity generating panels to each other, said locking assembly being configured to be securable to said support structure, said locking assembly including:
a spacer element operative to prevent said first and second solar electricity generating panels from being brought closer together to each other than in said mutually spaced arrangement in said plane; and
engagement elements operative to prevent lateral movement of said first and second solar electricity generating panels relative to said support structure.

13. A theft-protected array of solar electricity generating panels according to claim 12 and also comprising a tamper responsive protective cable extending through said locking assembly, whereby tampering with said locking assembly provides an alarm indication.

14. Anti-theft apparatus for protecting solar electricity generating panels from theft according to claim 2 and wherein each of said at least first and said at least second lockable elements are configured for engagement with a protective cable.

15. A theft-protected array of solar electricity generating panels according to claim 5 and also comprising a tamper responsive protective cable extending through said locking assembly, whereby tampering with said locking assembly provides an alarm indication.

16. Anti-theft apparatus for protecting solar electricity generating panels from theft according to claim 10 and wherein said apparatus is configured for engagement with a protective cable.
